(19) United States
(12) Patent Application Publication
(10) Pub. No.: US 2025/0313104 A1
(43) Pub. Date: Oct. 9, 2025

(54) CIRCUIT ARRANGEMENT FOR CONTROLLING A CHARGING CONTACTOR OF A CHARGING SYSTEM OF AN ELECTRICALLY OPERATED VEHICLE

(71) Applicant: MERCEDES-BENZ GROUP AG, Stuttgart (DE)

(72) Inventor: Maximilian HENGER, Backnang (DE)

(21) Appl. No.: 19/170,263

(22) Filed: Apr. 4, 2025

(30) Foreign Application Priority Data
Apr. 5, 2024 (DE) 10 2024 001 086.6

(51) Int. Cl. B60L 53/16; B60L 53/10; B60L 53/62

(52) U.S. Cl. CPC B60L 53/16; B60L 53/11; B60L 53/62

(57) ABSTRACT

A circuit arrangement for controlling at least one charging contactor of a charging system of an electrically operated vehicle includes at least one differential amplifier having two inputs and one output. The first input is electrically coupled to a first pole of an input voltage supply of the charging system for supplying an input voltage and the second input is electrically coupled to a second pole of the input voltage supply. The arrangement also includes a comparator having two inputs and one output. The first input is electrically coupled to the output of the differential amplifier and the output is electrically coupled to a control cable of the at least one charging contactor of the charging system.

### CROSS-REFERENCE TO RELATED APPLICATIONS

This application claims priority under 35 U.S.C. § 119 to German patent application DE 10 2024 001 086.6, filed on Apr. 5, 2024, the entire content of which is herein expressly incorporated by reference.

### BACKGROUND AND SUMMARY OF THE INVENTION

Exemplary embodiments of the invention relate to a circuit arrangement for controlling at least one charging contactor of a charging system of an electrically operated vehicle.

A charging port of an electrically operated vehicle, according to the NACS standard (North American Charging Standard) valid in North America, enables both direct current charging as well as alternating current charging. The special feature of this standard is the dual use of contacts inside the charging plug depending on the voltage type. Accordingly, the voltage type (direct current or alternating current configuration) provided by the charging station and applied to the plug has to be reliably detected. The NACS standard requires closing of direct current charging contactors according to the highest safety classification ASIL D (ASIL=Automotive Safety Integrity Level according to ISO 26262:2018 standard).

Exemplary embodiments of the present invention are directed to a circuit arrangement for controlling at least one charging contactor of a charging system of an electrically operated vehicle, which enables safe detection of the voltage type.

According to one aspect of the invention, a circuit arrangement for controlling at least one charging contactor of a charging system of an electrically operated vehicle is proposed, comprising at least one differential amplifier having two inputs and one output. In one operating state of the circuit arrangement, the first input of the differential amplifier is electrically coupled to a first pole of an input voltage supply of the charging system for supplying an input voltage and the second input is electrically coupled to a second pole of the input voltage supply of the charging system. The circuit arrangement also comprises a comparator having two inputs and one output, the first input of which is electrically coupled to the output of the differential amplifier and the output of which is electrically coupled to a control cable of the at least one charging contactor of the charging system in the operating state of the circuit arrangement.

Advantageously, with the proposed circuit arrangement, the voltage type (direct current or alternating current) can be safely detected by way of the hardware design of the circuit arrangement itself, wherein for this purpose a differential operational amplifier having an integrated low-pass filter and an adjoining comparator is used. A unique digital level is generated via the comparator stage. With a level of “one” (high) at the comparator output, direct current is above a limit value. With a level of “zero” (low), the direct current is below the limit value or there is alternating current.

It can be decided using the voltage type, whether the at least one charging contactor of the charging system can be closed. The control of the at least one charging contactor can conveniently take place via the output signal of the comparator.

The voltage type can be detected in a safe way with the circuit arrangement, and closing the at least one charging contactor can be controlled.

Advantageously, the voltage detection circuit itself does not require any software. Therefore, the high requirements of the safety objectives of the NACS standard can be realized in a simple manner.

Advantageously, an existing battery management system that fulfils ASIL level C does not have to be upgraded to ASIL level D. This eliminates software and hardware costs compared to a battery management system with ASIL level D.

According to an advantageous embodiment of the circuit arrangement, a low-pass filter can be arranged between the output of the differential amplifier and its second input. In particular, the low-pass filter can have at least one capacitor and a resistor connected electrically in parallel with the capacitor. Alternating voltage components can be conveniently eliminated by means of the low-pass filter.

According to an advantageous embodiment of the circuit arrangement, a first voltage divider for adjusting the input voltage to the inputs of the differential amplifier can be arranged at the two inputs of the differential amplifier. The voltage at the inputs of the differential amplifier can thus be conveniently limited to the required input voltage of the differential amplifier.

According to an advantageous embodiment of the circuit arrangement, a second voltage divider for setting a switching threshold of the comparator can be arranged at the second input of the comparator. This makes it possible to conveniently set the switching threshold above which a DC voltage is safely detected and a level of one is issued.

According to an advantageous embodiment of the circuit arrangement, a first galvanic isolation component, which is designed for issuing diagnostic information, can be arranged at the output of the comparator. In particular, the first galvanic isolation component can have an optical coupler. Thus, a switching state of the detection circuit can be issued to a vehicle control device for further processing.

According to an advantageous embodiment of the circuit arrangement, a third voltage divider for adjusting an output signal of the comparator can be arranged at the output of the comparator. Therefore, the voltage level of the output signal can be adjusted to an input of a following optical coupler of the control stage of the at least one charging contactor.

According to an advantageous embodiment of the circuit arrangement, a second galvanic isolation component can be arranged between the output of the comparator and the driver of the at least one charging contactor. In particular, the second galvanic isolation component can follow the first galvanic isolation component. In particular, the second galvanic isolation component can have an optical coupler. Conveniently, safe galvanic isolation can thus take place due to the different electric potentials between the high-voltage battery and the low-voltage on-board voltage.

According to an advantageous embodiment of the circuit arrangement, a bistable circuit can be arranged at the output of the second galvanic isolation component. Opening of the at least one charging contactor by the voltage detection circuit alone can be prevented by means of such a so-called latch circuit.

According to an advantageous embodiment of the circuit arrangement, a logic component can be arranged between the output of the bistable component and an input of the driver of the at least one charging contactor. In this case, a first input of the logic component can be electrically coupled to the output of the bistable component and a second input of the logic component can be electrically coupled to a control signal of a vehicle control device. By way of an additional input signal via the logic component, there is yet another approval that has to be handled by the software. This means that the opening of the at least one charging contactor can be commanded at any time.

According to an advantageous embodiment of the circuit arrangement, the logic component can be designed as an adder. Therefore, a state “one” for opening the at least one charging contactor can only be output when an input from the voltage detection circuit and from the additional input signal is “one” in each case.

Further advantages result from the following drawing description. In the drawings, an exemplary embodiment of the invention is represented. The drawings, the description and the claims include numerous features in combination. The person skilled in the art will also expediently consider the features individually and combine them into useful further combinations.

### BRIEF DESCRIPTION OF THE DRAWING FIGURES

In the drawings:

FIG. 1 shows a system overview of a circuit arrangement for controlling at least one charging contactor of a charging system of an electrically operated vehicle according to one exemplary embodiment of the invention;

FIG. 2 shows a voltage detection circuit as a part of the circuit arrangement according to FIG. 1 for detecting a voltage type of the input voltage; and

FIG. 3 shows a further part of the circuit arrangement according to FIG. 1 for controlling the at least one charging contactor.

In the figures, identical or similar components are provided with the same reference numerals. The figures only show examples and are not intended to be restrictive.

### DETAILED DESCRIPTION

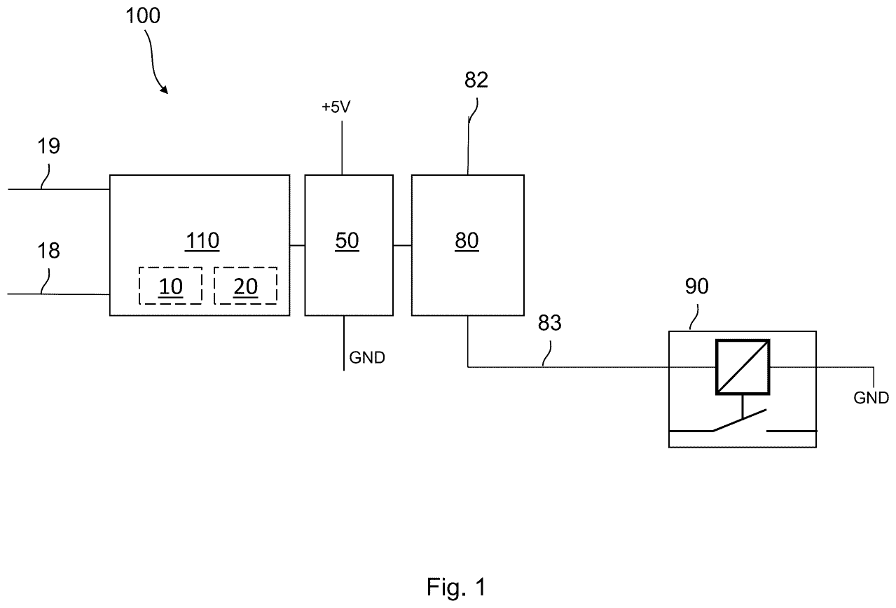

FIG. 1 shows a system overview of a circuit arrangement 100 for controlling at least one charging contactor 90 of a charging system of an electrically operated vehicle according to one exemplary embodiment of the invention.

The circuit arrangement 100 comprises a voltage detection circuit 110, which has at least one differential amplifier 10 and one comparator 20. The voltage detection circuit 110 is electrically coupled to a first pole 18 of an input voltage supply for supplying an input voltage and to a second pole 19 of the input voltage supply of the charging system.

The output of the voltage detection circuit 110 is electrically connected to a driver 80 of the at least one charging contactor 90 via a galvanic isolation component 50, for example an optical coupler 51. The galvanic isolation component 50 is connected to a voltage of +5V and the ground GND. The driver 80 obtains an electric supply voltage for the at least one charging contactor 90 via a cable 82.

The driver 80 controls the at least one charging contactor 90 via a control cable 83. The charging contactor 90 is similarly connected to the ground GND.

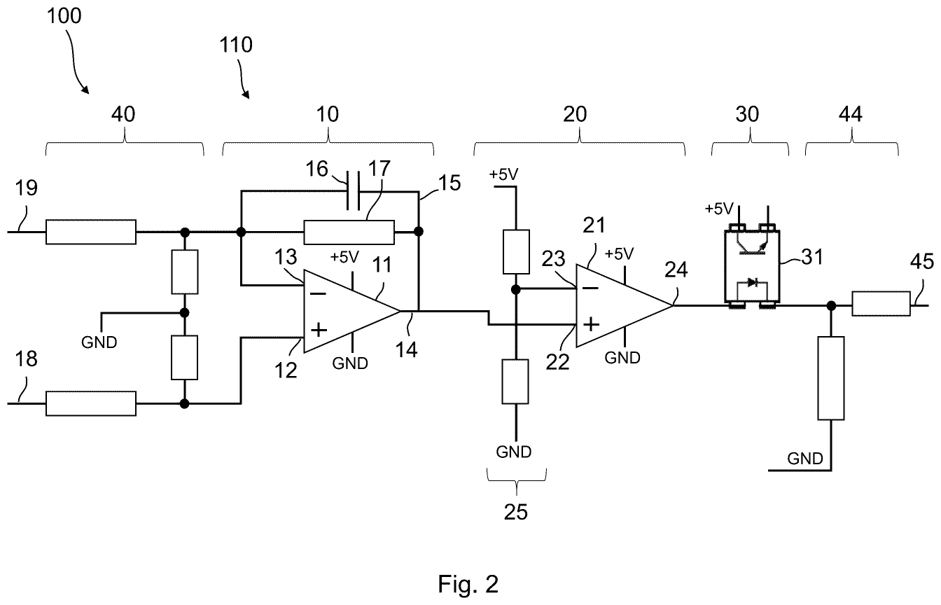

FIG. 2 shows the voltage detection circuit 110 as a part of the circuit arrangement 100 according to FIG. 1 for detecting a voltage type of the input voltage.

The voltage detection circuit 110 comprises the differential amplifier 10, which is designed as a differential operational amplifier 11 having two inputs 12, 13 and one output 14, and the first input 12 of which is electrically coupled to the first pole 18 of the input voltage supply and the second input 13 of which is electrically coupled to the second pole 19 of the input voltage supply of the charging system.

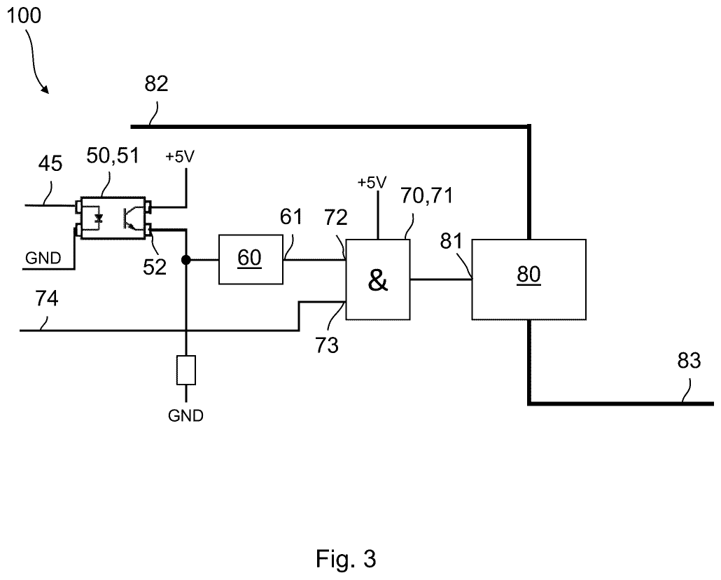

The voltage detection circuit 110 also comprises the comparator 20 which is designed as a comparator component 21 having two inputs 22, 23 and one output 24, and the first input 22 of which is electrically coupled to the output 14 of the differential amplifier 10 and the output 24 of which is electrically coupled to the control cable 83 (FIG. 1 and FIG. 3) of the at least one charging contactor 90 of the charging system.

The differential amplifier 10 and comparator 20 are connected to a voltage of +5V and the ground GND.

A low-pass filter 15, which has a capacitor 16 and a resistor 17 connected electrically in parallel with the capacitor 16, is arranged between the output 14 of the differential amplifier 10 and its second input 13. Alternating voltage components of the input voltage can be conveniently eliminated by means of the low-pass filter 15.

A first voltage divider 40 for adjusting the input voltage to the inputs 12, 13 of the differential amplifier 10 is arranged at the two inputs 12, 13 of the differential amplifier 10. In each case, the voltage divider 40 consists of two resistors, connected in series between the first pole 18 or the second pole 19 and the ground GND, the center taps of which are connected to the first input 12 or the second input 13. The voltage at the inputs 12, 13 of the differential amplifier 10 can thus be conveniently limited to the required input voltage of the differential amplifier 10.

A second voltage divider 25 for setting a switching threshold of the comparator 20 is arranged at the second input 23 of the comparator 20. The second voltage divider 25 consists of two resistors connected in series between the voltage +5V and the ground GND, the center tap of which is connected to the second input 23 of the comparator 20. This makes it possible to conveniently set the switching threshold above which a DC voltage is safely detected and a level of one is issued.

A first galvanic isolation component 30, which is designed for issuing diagnostic information, is arranged at the output 24 of the comparator 20. The first galvanic isolation component 30 can be designed as an optical coupler 31, for example. Thus, a switching state of the detection circuit can be issued to a vehicle control device for further processing. The signal transmission can therefore take place via an LED or a phototransistor.

The diagnosis can be carried out by means of a control device and/or vehicle software. This means that a diagnosis and plausibility check of the voltage detection circuit 110 can be carried out taking into consideration further parameters, in particular matching the charging point voltage to the battery voltage of the vehicle high-voltage battery to be charged.

Arranged at the output 24 of the comparator 20 is a third voltage divider 44 having a resistor connected in series and a resistor connected to the ground GND for adjusting an output signal of the comparator 20. An output signal 45 of the voltage detection circuit 110 is present after the third voltage divider 44. Therefore, the voltage level of the output signal can be adjusted to an input of a following optical coupler 51 of the control stage of the at least one charging contactor 90.

FIG. 3 shows a further part of the circuit arrangement 100 according to FIG. 1 for controlling the at least one charging contactor 90.

A second galvanic isolation component 50 is arranged between the output 24 of the comparator 20 and the driver 80 of the at least one charging contactor 90.

The second galvanic isolation component 50 thus follows the first galvanic isolation component 30 and can similarly be designed as an optical coupler 51. Conveniently, safe galvanic isolation can thus take place due to the different electric potentials between the high-voltage battery and the low-voltage on-board voltage.

The second galvanic isolation component 50 is coupled to the output signal 45 of the voltage detection circuit 110. The second galvanic isolation component 50 is connected to the voltage +5V and the ground GND for electrical supply.

A bistable circuit 60 is arranged at the output 52 of the second galvanic isolation component 50. By means of such a so-called latch circuit, opening of the at least one charging contactor 90 by the voltage detection circuit 110 alone can be prevented.

A further logic component 70 is arranged between the output 61 of the bistable component 60 and an input 81 of the driver 80 of the at least one charging contactor 90.

A first input 72 of the logic component 70 is electrically coupled to the output 61 of the bistable component 60 and a second input 73 of the logic component 70 is electrically coupled to a control signal 74 of a vehicle control device.

By way of an additional input signal 74 via the logic component 70, there is yet another approval which has to be handled by the software. This means that the opening of at least one charging contactor 90 can be commanded at any time

In particular, checking the voltage level between charging point and a high-voltage battery of the vehicle can take place in this manner. Closing the at least one charging contactor 90 only takes place when the two voltages match.

The control device has a lower functional safety than the proposed circuit arrangement 100.

The logic component 70 can be designed as an adder 71, for example. Therefore, a state “one” for opening the at least one charging contactor 90 can only be issued when an input from the voltage detection circuit 110 and from the additional input signal 74 is “one” in each case.

The output signal of the driver 80 serves as a control signal 83 to open or close the at least one charging contactor 90 of the charging system of the vehicle.

Although the invention has been illustrated and described in detail by way of preferred embodiments, the invention is not limited by the examples disclosed, and other variations can be derived from these by the person skilled in the art without leaving the scope of the invention. It is therefore clear that there is a plurality of possible variations. It is also clear that embodiments stated by way of example are only really examples that are not to be seen as limiting the scope, application possibilities or configuration of the invention in any way. In fact, the preceding description and the description of the figures enable the person skilled in the art to implement the exemplary embodiments in concrete manner, wherein, with the knowledge of the disclosed inventive concept, the person skilled in the art is able to undertake various changes, for example, with regard to the functioning or arrangement of individual elements stated in an exemplary embodiment without leaving the scope of the invention, which is defined by the claims and their legal equivalents, such as further explanations in the description.

### LIST OF REFERENCE NUMERALS

10 differential amplifier
11 differential operational amplifier
12 first input
13 second input
14 output
15 low-pass filter
16 capacitor
17 resistor
18 first pole
19 second pole
20 comparator
21 comparator component
22 first input
23 second input
24 output
25 second voltage divider
30 first galvanic isolation component
31 optical coupler
40 second voltage divider
44 third voltage divider
45 output signal
50 second galvanic isolation component
51 optical coupler
52 output
60 bistable circuit
61 output
70 logic component
71 adder
72 first input
73 second input
80 driver
81 input for driver
82 voltage supply for charging contactor
83 control cable
90 charging contactor
100 circuit arrangement
110 voltage detection circuit

What is claimed is:

1. A circuit arrangement for controlling at least one charging contactor of a charging system of an electrically operated vehicle, the circuit arrangement comprising:
a differential amplifier having first and second inputs and one output, wherein the first input is electrically coupled to a first pole of an input voltage supply of the charging system configured to supply an input voltage and the second input is electrically coupled to a second pole of the input voltage supply; and
comparator having first and second inputs and one output, wherein the first input of the comparator is electrically coupled to the output of the differential amplifier and the output of the comparator is electrically coupled to a control cable of the at least one charging contactor of the charging system.

2. The circuit arrangement of claim 1, further comprising:
a low-pass filter arranged between the output of the differential amplifier and the second input of the differential amplifier,
wherein the low-pass filter has at least one capacitor and a resistor connected electrically in parallel with the capacitor.

3. The circuit arrangement of claim 1, further comprising:
a first voltage divider configured to adjust an input voltage to the first and second inputs of the differential amplifier, wherein the first voltage divider is arranged at the first and second inputs of the differential amplifier.

4. The circuit arrangement of claim 3, further comprising:
a second voltage divider configured to set a switching threshold of the comparator, wherein the second voltage divider is arranged at the second input of the comparator.

5. The circuit arrangement of claim 1, further comprising:
a first galvanic isolation component configured to issue diagnostic information, wherein the first galvanic isolation component is arranged at the output of the comparator, and wherein the first galvanic isolation component has an optical coupler.

6. The circuit arrangement of claim 5, further comprising:
a third voltage divider configured to adjust an output signal of the comparator, wherein the third voltage divider is arranged at the output of the comparator.

7. The circuit arrangement of claim 5, further comprising:
a second galvanic isolation component arranged between the output of the comparator and a driver of the at least one charging contactor, wherein the second galvanic isolation component follows the first galvanic isolation component, and the second galvanic isolation component has an optical coupler.

8. The circuit arrangement of claim 7, further comprising:
a bistable circuit at an output of the second galvanic isolation component.

9. The circuit arrangement of claim 8, further comprising:
a logic component arranged between an output of the bistable circuit and an input of the driver of the at least one charging contactor, wherein a first input of the logic component is electrically coupled to an output of the bistable circuit and a second input of the logic component is electrically coupled to a control signal of a vehicle control device.

10. The circuit arrangement of claim 9, wherein the logic component is an adder.
